(19) United States
(12) Patent Application Publication
(10) Pub. No.: US 2026/0147029 A1
(43) Pub. Date: May 28, 2026

(54) SYSTEM AND METHOD FOR DETERMINING AN OPTIMIZED DESIGN FOR A MULTI-LAYER RADOME

(71) Applicant: The Boeing Company, Arlington, VA (US)

(72) Inventor: Daniel Alan Durbin, Glen Carbon, IL (US)

(73) Assignee: The Boeing Company, Arlington, VA (US)

(21) Appl. No.: 18/962,535

(22) Filed: Nov. 27, 2024

(51) Int. Cl. G01R 29/08; H01Q 1/42

(52) U.S. Cl. CPC G01R 29/0807; H01Q 1/422

(57) ABSTRACT

A system and method for determining an optimized design for a multi-layer radome, wherein the radome has a radome wall made of stacked layers and longitudinally contiguous segments each having a segment location. Each layer has electrical properties and a thickness that varies by segment location; a value is provided for the thickness of each layer for each segment, thereby producing a thickness profile; a radome performance is assessed using the thickness profile in a cost function, thereby producing a thickness profile performance; one or more of the thicknesses are iterated using an iteration algorithm, thereby producing an additional thickness profile; the radome performance is re-assessed using the additional thickness profile in the cost function, thereby producing an additional thickness profile performance; the iterating and re-assessing steps are repeated; and the thickness profile producing a best one of the thickness profile performances is determined, thereby defining the optimized design.

### INTRODUCTION

This disclosure relates generally to multi-layer radomes, and more particularly to systems and methods for determining an optimized design for a multi-layer radome.

A radome (short for “radar dome”) is a removable housing which is used to cover and protect a radar array or antenna from direct exposure to the elements. Some radomes cover radar arrays on ground-based radar units, while other radomes may cover radar arrays on aircraft (e.g., such as those located within the nose cone at the front of the fuselage) as well as on surface and submersible watercraft.

So-called “sandwich” radomes are composed of alternating layers of relatively high density skin materials (e.g., quartz composites or E-glass) and relatively low density core materials (e.g., polyetherimide in a foamed or honeycomb form). Alternatively, the radome may be formed as a composition of ceramics or other materials. Due to the geometric shape of a radome and where the radar array or antenna is placed inside the radome, the walls of the radome can dramatically affect the transmission, reflection and other characteristics of the radio frequency energy being transmitted and received by the radar array or antenna. Moreover, this effect may not be uniform for all portions of the radome wall.

One way of addressing this effect is to vary the thicknesses of the layers that make up the radome wall sandwich or composition, and to do so differentially across some or all portions of the radome wall. However, this approach has heretofore been done manually, requiring skilled and experienced engineers or technicians to do so, and normally involving substantial trial and error.

### SUMMARY

According to one embodiment, a method for determining an optimized design for a multi-layer radome is provided, wherein the radome has a main axis defining radial and longitudinal directions and a radome wall made of stacked layers and longitudinally contiguous segments with each segment having a respective segment location, and with the radome being configured for housing an antenna that is positioned therein at an antenna location. The method includes: (i) characterizing each of the layers as having a respective set of one or more electrical properties and a respective thickness that varies by segment location along the main axis; (ii) providing a respective value for the thickness of each of the layers for each of the segments, thereby producing a thickness profile; (iii) assessing a performance of the radome with respect to one or more performance goals using the thickness profile in a cost function, thereby producing a thickness profile performance; (iv) iterating one or more of the respective thicknesses at one or more of the segment locations by using an iteration algorithm, thereby producing an additional thickness profile; (v) re-assessing the performance of the radome with respect to the one or more performance goals using the additional thickness profile in the cost function, thereby producing an additional thickness profile performance; (vi) repeating the iterating and re-assessing steps for a number of iterations; and (vii) determining the thickness profile which produces a best one of the thickness profile performances, thereby defining the optimized design for the radome.

The one or more electrical properties may include at least one of a dielectric constant, a loss tangent, a complex permittivity and a complex permeability, and the respective value for each thickness may be identified from one or more of a look-up table, user input and machine learning based on data from previous instances of radome optimization.

In each of the providing and iterating steps, the respective thickness of each layer for each segment may be selected from between a respective predetermined minimum thickness and a respective predetermined maximum thickness.

The performance goals may include one or more of maximizing transmission of radio frequency (RF) energy, minimizing reflection of RF energy, maximizing a bandwidth of RF energy, optimizing a polarization of RF energy and optimizing a phase insertion of RF energy.

The cost function may be configured to assess an impact, over a range of scan angles and over a range of frequencies, of one or more of: (a) a perpendicular component of reflection of radio frequency (RF) energy emitted from the antenna at the antenna location to each of the segment locations; (b) a perpendicular component of transmission of the RF energy; (c) a parallel component of reflection of the RF energy; (d) a parallel component of transmission of the RF energy; (c) a polarization of the RF energy; and (f) a phase insertion of the RF energy.

The iteration algorithm may be one or more of a particle swarm optimization algorithm, a simulated annealing algorithm, a greedy local search algorithm, a nearest neighbor algorithm, a branch and bound algorithm, a gradient descent algorithm, a genetic algorithm, a stochastic algorithm and a brute force approach.

The number of iterations may be at least one of a predetermined number and a quantity sufficient to achieve a thickness profile performance that meets or exceeds a target thickness profile performance.

The method may further include generating an output file which includes the thickness profile that produces the best one of the thickness profile performances. For example, the output file may include computer numerically controlled (CNC) instructions configured for use by a CNC machine for producing the radome. Relatedly, the method may further include producing the radome by a CNC machine using the output file.

The method may further include outputting a signal configured for enabling a visualization of one or more of: (i) a progression of the thickness profiles produced as the iterating and re-assessing steps are repeated for the number of iterations; (ii) a progression of the performance as the iterating and re-assessing steps are repeated for the number of iterations; and (iii) the thickness profile which produces the best one of the thickness profile performances.

The layers may include alternating layers of one or more skin materials and one or more core materials, wherein the one or more skin materials may include at least one of a quartz composite, an E-glass, a D-glass, a polyethylene and an aromatic polyamide, and wherein the one or more core materials may include at least one of a polyetherimide, a polymethacrylimide, a polyurethane, a polycarbonate, a polyimide, a fluoropolymer, a polyaryletherketone, an acrylonitrile butadiene styrene and a composite material.

The radome may be configured as a volume of revolution and the main axis may be an axis of revolution. Additionally or alternatively, the radome may have one of a generally spherical shape, a generally hemispherical shape, a generally geodesic shape, a generally elliptical shape and a generally ogive shape.

A multi-layer radome may also be produced by the method of claim 1.

According to another embodiment, a method for determining an optimized design for a multi-layer radome is provided. In this embodiment, the radome has a main axis defining radial and longitudinal directions and a radome wall made of stacked layers and longitudinally contiguous segments with each segment having a respective segment location, with the radome being configured for housing an antenna that is positioned therein at an antenna location. The method includes: (i) characterizing each of the layers as having a respective set of one or more electrical properties and a respective thickness that varies by segment location along the main axis, wherein the one or more dielectric properties includes at least one of a dielectric constant, a loss tangent, a complex permittivity and a complex permeability; (ii) providing a respective value for the thickness of each of the layers for each of the segments, thereby producing a thickness profile; (iii) assessing a performance of the radome with respect to one or more performance goals using the thickness profile in a cost function, thereby producing a thickness profile performance, wherein the performance goals include one or more of maximizing transmission of radio frequency (RF) energy, minimizing reflection of RF energy, maximizing a bandwidth of RF energy, optimizing a polarization of RF energy, and optimizing a phase insertion of RF energy; (iv) iterating one or more of the respective thicknesses at one or more of the segment locations by using an iteration algorithm, thereby producing an additional thickness profile; (v) re-assessing the performance of the radome with respect to the one or more performance goals using the additional thickness profile in the cost function, thereby producing an additional thickness profile performance; (vi) repeating the iterating and re-assessing steps for a number of iterations, wherein the number of iterations is at least one of a predetermined number and a quantity sufficient to achieve a thickness profile performance that meets or exceeds a target thickness profile performance; and (vii) determining the thickness profile which produces a best one of the thickness profile performances, thereby defining the optimized design for the radome.

According to yet another embodiment, a system for determining an optimized design for a multi-layer radome is provided, wherein the radome has a main axis defining radial and longitudinal directions and a radome wall made of stacked layers and longitudinally contiguous segments with each segment having a respective segment location, with the radome being configured for housing an antenna that is positioned therein at an antenna location. The system includes an input subsystem, a processor and an output subsystem. The input subsystem is configured for receiving one or more inputs from a user or another source or device regarding one or more aspects of the radome and for producing an input signal based on the one or more inputs. The processor is configured for receiving the input signal from the input subsystem and for: (i) characterizing each of the layers as having a respective set of one or more electrical properties and a respective thickness that varies by segment location along the main axis; (ii) providing a respective value for the thickness of each of the layers for each of the segments, thereby producing a thickness profile; (iii) assessing a performance of the radome with respect to one or more performance goals using the thickness profile in a cost function, thereby producing a thickness profile performance; (iv) iterating one or more of the respective thicknesses at one or more of the segment locations by using an iteration algorithm, thereby producing an additional thickness profile; (v) re-assessing the performance of the radome with respect to the one or more performance goals using the additional thickness profile in the cost function, thereby producing an additional thickness profile performance; (vi) repeating the iterating and re-assessing steps for a number of iterations; and (vii) determining the thickness profile which produces a best one of the thickness profile performances, thereby defining the optimized design for the radome. The output subsystem is configured for receiving from the processor, and for producing an output signal based on, one or both of (a) the thickness profiles produced as the iterating and re-assessing steps are repeated for the number of iterations, and (b) the thickness profile which produces the best one of the thickness profile performances.

The one or more inputs may include one or more of a geometric shape of the radome, a size of the radome, a quantity of the layers in the radome wall, the antenna location with respect to the radome, one or more of the respective electrical properties of one or more of the layers, and one or more of the respective thicknesses of one or more of the layers.

The system may further include a visualization subsystem configured for receiving the output signal from the output subsystem and for enabling a visualization of one or more of a progression of the thickness profiles produced as the iterating and re-assessing steps are repeated for the number of iterations, a progression of the performance as the iterating and re-assessing steps are repeated for the number of iterations, and the thickness profile which produces the best one of the thickness profile performances.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

FIG. 1 is a schematic cross-sectional side view of an elliptical-shaped radome made of multiple longitudinally contiguous segments.

FIGS. 2-3 are close-up views of segments G and V from FIG. 1, each showing a stack of alternating layers.

FIG. 4 is a block diagram of materials for the layers of a radome.

FIG. 5 is a block diagram of electrical properties for the layers of a radome.

FIG. 6 is a block diagram of various radome shapes for the radome.

FIG. 7 is a block diagram of performance goals for the performance of a radome.

FIG. 8 is a block diagram of various iteration algorithms.

FIG. 9 is a flowchart for a method for determining an optimized design for a multi-layer radome.

FIG. 10 is a block diagram of a system for determining an optimized design for a multi-layer radome.

### DETAILED DESCRIPTION

Referring now to the drawings, wherein like numerals indicate like parts in the several views, a method 100 and system 200 for determining an optimized design 10ₒₚₜ for a multi-layer radome 10 are shown and described herein.

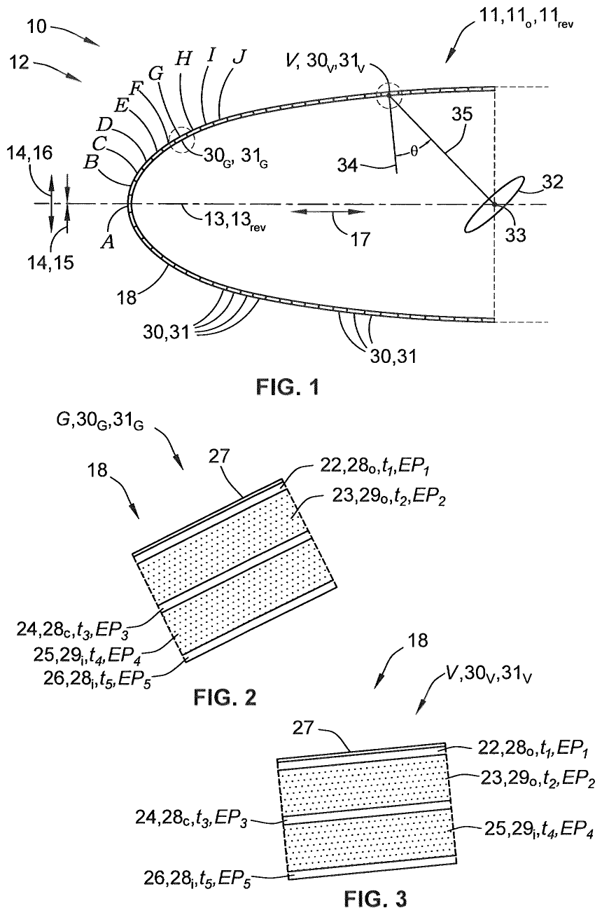

FIG. 1 shows a schematic cross-sectional side view of an exemplary radome 10.

In this example, the radome 10 has an overall geometric shape 11 that is a generally elliptical shape 11ₑ, with the radome 10 having an overall size 12 that is large enough to enclose or cover an antenna 32 that is situated at an antenna location 33. The radome 10 has a main axis 13 which defines a radial direction 14 which points toward the main axis 13 (i.e., an inward direction 15) and away from the main axis 13 (i.e., an outward direction 16), as well as a longitudinal direction 17 which points along the main axis 13.

The radome 10 also has a radome wall 18 that may be viewed as being made up of a continuous series of longitudinally contiguous segments 30, with each segment 30 having a respective segment location 33 along or with respect to the main axis 13. Note that in FIG. 1, the segments 30 have been labeled alphabetically for the sake of reference. For example, the nose or vertex is labeled as segment A, then segments B, C, D, etc. up through J, and then skipping to segment V. If the shape 11 of the radome 10 is that of a volume of revolution 11ᵣₑᵥ, such as a relatively thin, arcuately shaped shell being revolved about the main axis 13 (thus making the main axis 13 an axis of revolution 13ᵣₑᵥ), then each of segments B, C, D, etc. may be viewed as being generally annular or ring-shaped, with segment A being shaped as a “cap”, a disc or the like.

Note that segments G and V are highlighted with dashed circles in FIG. 1. Here, segment G is also designated as segment 30_{G} situated at segment location 31_{G}, and segment V is also designated as segment 30_{V} situated at segment location 31_{V}. The drawing shows a first line 34 extending in an inward direction 15 from segment V, with this first line 34 being normal to the curved surface of the radome wall 18. The schematic representation of the antenna 32 is shown directing its radio frequency (RF) energy toward segment V, as represented by a second line 35 extending from the antenna location 33 to segment V. A respective angle of incidence θ is shown for this segment V, 30_{V} and segment location 31_{V}, with the angle of incidence θ spanning between the first line 34 and the second line 35. Those skilled in the art relating to radomes will appreciate that the antenna 32 may rotate about its antenna location 33, or the antenna 32 may remain fixed and its RF energy may be steered, such that the RF energy is swept through a range of scan angles R_{scan angles} and over a range of frequencies R_{freqs}.

FIGS. 2-3 show close-up cross-sectional views of segments G and V from FIG. 1. As shown here, each segment 30 is made up a quantity L of stacked or sandwiched layers 20, which may be alternating layers 21 of skin material 28 and core material 29 or other compositional arrangements. For example, the radome wall 18 shown in the cross-sections of FIGS. 2-3 is made of five layers 20 (i.e., L=5), with each layer 20 having its own respective thickness t and its own respective set of one or more electrical properties EP. (Note that as used herein, “EP” may represent a single electrical property and/or a set of two or more electrical properties.) Practically speaking, the material used for each layer 20—and thus the layer's electrical properties EP—may be the same along the full length of the layer 20 (i.e., isotropic, from segment A at the vertex to the base of the radome 10 where the radome 10 is attached to an aircraft, a boat, a ground-based platform, etc.). However, note that the thickness t for each layer 20 may vary along the length of the layer 20 (i.e., along the main axis 13 and longitudinal direction 17).

As shown in FIGS. 2-3, the five layers 20 of the exemplary radome wall 18 include: (i) an outer skin 22 (made of an outer skin material 28, having a first electrical property EP₁ and a first thickness t₁); (ii) an outer core 23 (made of an outer core material 29, having a second electrical property EP₂ and a second thickness t₂) that is attached to and disposed radially inward of the outer skin 22; (iii) a center skin 24 (made of a center skin material 28, having a third electrical property EP₃ and a third thickness t₃) that is attached to and disposed radially inward of the outer core 23; (iv) an inner core 25 (made of an inner core material 29; having a fourth electrical property EP₄ and a fourth thickness t₄) that is attached to and disposed radially inward of the center skin 24; and (v) an inner skin 26 (made of an inner skin material 28; having a fifth electrical property EP₅ and a fifth thickness t₅) that is attached to and disposed radially inward of the inner core 25. Note that although the radome wall 18 shown here has five layers 20 (i.e., L=5), other configurations of the radome wall 18 may include more or less than five layers 20. Optionally, a coating 27 may be attached to and disposed radially outward of the outer skin 22; this coating 27 may be made of a hydrophobic material which may help wick water away from the outer surface of the radome 10. Note that the various layers 20 and coating 27 are depicted schematically are not necessarily drawn to scale. These various layers 20, the coating 27, and their respective materials, electrical properties EP and thicknesses t may be summarized as shown in TABLE 1 below:

TABLE 1
Layer Characteristics

| | | | Electrical | Thick- |
|---|---|---|---|---|
| Ref. Num. | Layer | Material | Property(-ies) | ness |
| 22 | Outer skin | Outer skin | EP₁ | t₁ |
| | | material 28ₒ | | |
| 23 | Outer core | Outer core | EP₂ | t₂ |
| | | material 29ₒ | | |
| 24 | Center skin | Center skin | EP₃ | t₃ |
| | | material 28_{c} | | |
| 25 | Inner core | Inner core | EP₄ | t₄ |
| | | material 29ᵢ | | |
| 26 | Inner skin | Inner skin | EP₅ | t₅ |
| | | material 28ᵢ | | |
| 27 | Coating | Hydrophobic | — | — |
| | | material | | |

It may be noted that the outer skin material 28ₒ, the center skin material 28_{c} and the inner skin material 28ᵢ may all be the same skin material 28, while the outer core material 29ₒ and the inner core material 29ᵢ may both be the same core material 29. However, in such an arrangement, the respective thicknesses t₁, t₃, t₅ of the skin layers 22, 24, 26 may be different from each other, and the respective thicknesses t₂, t₄ of the core layers 23, 25 may also be different from each other. Further, as noted above, the thickness t for any given layer 20 may vary from segment 30 to segment 30 along the length of the main axis 13.

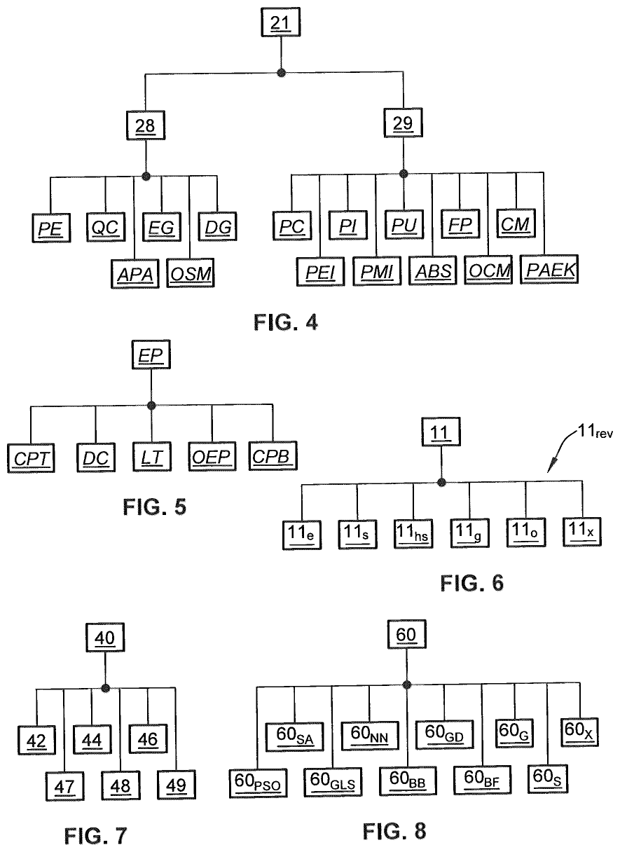

FIG. 4 shows a block diagram of materials that may be used for the layers 20 of the radome 10. For example, the skin materials 28 may include one or more of a quartz composite QC (such as quartz cyanate ester), an E-glass EG, a D-glass DG, a polyethylene PE, an aromatic polyamide APA or aramid (e.g., Kevlar® fiber) or some other skin material OSM. Additionally, the core materials 29 may include one or more of a polyetherimide PEI, a polymethacrylimide PMI, a polyurethane PU, a polycarbonate PC, a polyimide PI, a fluoropolymer FP, a polyaryletherketone PAEK, an acrylonitrile butadiene styrene ABS, a composite material CM (e.g., a fiberglass and resin composite) or some other core material OCM. In some configurations, the core materials 29 may have a larger thickness t than the skin materials 28, with the core layers being made in the form of a honeycomb or a foam with small air pockets disposed therein. In other configurations, the composition of the radome 10 may include various ceramic materials, such as silicon carbide, alumina, silicon nitride and fused silica.

FIG. 5 shows a block diagram of various electrical properties EP for the layers 20 of the radome 10. These may include a dielectric constant DC (sometimes also called a relative permittivity), a loss tangent LT (sometimes also called a dielectric loss), a complex permittivity CPT, a complex permeability CPB or some other electrical and/or dielectric property OEP. In most configurations, it may be desirable that the dielectric constant DC and the loss tangent LT are each as low as practicable, and that the complex permittivity CPT and complex permeability CPB are optimized. Note that the electrical properties EP may include one or more dielectric properties.

FIG. 6 shows a block diagram of various radome shapes 11 for the radome 10. For example, the radome 10 may have a generally spherical shape 11ₛ, a generally hemispherical shape 11ₕₛ, a generally geodesic shape 11_{g}, a generally elliptical shape 11ₑ, a generally ogive shape 11ₒ or some suitable other shape 11ₓ.

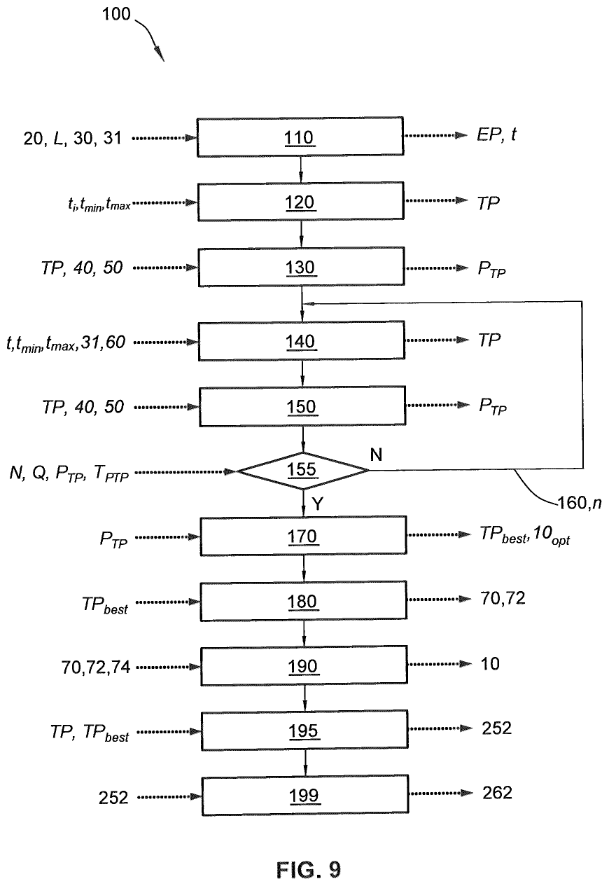

FIG. 9 shows a flowchart for a method 100 for determining an optimized design 10ₒₚₜ for a multi-layer radome 10 according to the present disclosure. Here, the radome 10 has a main axis 13 defining radial and longitudinal directions 14, 17 and a radome wall 18 made of stacked layers 20 and longitudinally contiguous segments 30 with each segment 30 having a respective segment location 31, and with the radome 10 being configured for housing an antenna 32 that is positioned therein at an antenna location 33. Note that the inputs for each block or step are shown to the left of each block or step, and the results or outputs produced by each block or step are shown to the right of each block or step.

At block 110, each of the layers 20 is parameterized or characterized as having a respective set of one or more electrical properties EP and a respective thickness t that varies by segment location 31 along the main axis 13. As noted above, the electrical property EP of a given layer 20 may optionally be the same for all segments 30 along the length of the main axis 13, such as when only one material is used for that layer 20. Alternatively, two or more materials may be used for a given layer, with some segments 30 using one material for that layer, other segments 30 using another material for that layer, and so forth.

At block 120, a respective initial value tᵢ is provided for the thickness t of each of the layers 20 for each of the segments 30, thereby producing an initial thickness profile TP. In other words, the initial thickness profile TP includes the initial thickness value tᵢ that is assigned to each layer 20 and in each segment 30. Optionally, a singular initial value tᵢ may be assigned as the thickness t for all of the segments 30 for a given layer 20, meaning that the thickness t for that layer 20 would be uniform along the length of the main axis 13 for the initial thickness profile TP. Alternatively, the initial value t; of the thickness t for a given layer 20 may vary from one segment 30 to the next, thus providing a varying and non-uniform thickness t for that layer 30 as viewed along the length of the main axis 13. In some configurations, the initial values tᵢ may be reflective of or based on one or more boundary conditions, features or dimensions of the radome 10 and/or of the radome wall 18, such as the radome shape 11, the radome size 12 (including various height, width, length or other measurements), the desired operational frequencies for the radome 10, etc. Additionally, the initial values tᵢ may be identified or selected from one or more of a look-up table LUT, one or more user inputs UI, and machine learning ML that is based on data DD compiled from previous instances PI (including manual instances) of attempts at radome optimization RO.

At block 130, a performance P of the radome 10 is assessed with respect to one or more performance goals 40, by using the initial thickness profile TP in a cost function 50, thereby producing an initial thickness profile performance P_{TP}. In some views, the thickness profile performance P_{TP} and the cost/impact Cost may be seen as being the same as each other, while in other views they may be seen as being directly or indirectly related to each other, such as through some suitable scaling factor, ratio, offset or the like.

FIG. 7 shows a block diagram of various performance goals 40 which may be used for evaluating the performance P of a radome 10. The performance goals 40 may include one or more of maximizing transmission 42 of RF energy, minimizing reflection 44 of RF energy, maximizing a bandwidth 46 of RF energy, optimizing a polarization 48 of RF energy, optimizing a phase insertion 47 of RF energy, or some other suitable performance goal 49.

The cost function 50 may assume various forms, such as the one shown in Equation 1 below:

$$Cost = {\sum }_{{R}_{f r e q s}} \{ {W}_{freq} [ {\sum }_{{R}_{scan angles}} {W}_{scan angle} ( {αΓ}_{⊥} + β {T}_{⊥} + {γΓ}_{‖} + δ {T}_{‖} ) ] \} \qquad ( Eqn . 1 )$$

As illustrated in the equation above, the cost function 50 may be configured to assess a cost or impact Cost, over a range of scan angles R_{scan angles} and over a range of frequencies R_{freqs}, of: (a) a perpendicular component of reflection Γ_{⊥} of RF energy emitted from the antenna 32 at the antenna location 33 to each of the segment locations 31; (b) a perpendicular component of transmission T_{⊥} of the RF energy; (c) a parallel component of reflection Γ_{∥} of the RF energy; and (d) a parallel component of transmission T_{∥} of the RF energy. The various coefficients shown in Eqn. 1—i.e., α, β, γ and δ—may be viewed as weighting factors for each of their respective variables. (Although not explicitly shown in the example of Eqn. 1, the cost function 50 may also assess a polarization 48 of the RF energy and a phase insertion 47 of the RF energy.)

Returning now to FIG. 9, at block 140, one or more of the respective thicknesses t at one or more of the segment locations 31 is/are iterated (e.g., perturbed, changed or updated stochastically) by using an iteration algorithm 60, thereby producing an additional (and somewhat different) thickness profile TP. That is, once the initial thickness profile TP has been established at block 120 and the performance P of the initial thickness profile TP has been assessed at block 130, then one or more of the thicknesses t at one or more of the segments 30 may be iterated at block 140 to produce the additional thickness profile TP.

FIG. 8 shows a block diagram of various iteration algorithms 60. The iteration algorithm 60 may include one or more of a particle swarm optimization algorithm 60_{PSO}, a simulated annealing algorithm 60_{SA}, a greedy local search algorithm 60_{GLS}, a nearest neighbor algorithm 60_{NN}, a branch and bound algorithm 60_{BB}, a gradient descent algorithm 60_{GD}, a genetic algorithm 60_{G}, a stochastic algorithm 60_{S} and a brute force approach 60_{BF}. Other forms 60_{X} of iteration algorithms 60 may be used as well.

In each of the providing and iterating steps (of blocks 120 and 140, respectively), the respective thickness t of each layer 20 for each segment 30 may be selected from between a respective predetermined minimum thickness tₘᵢₙ and a respective predetermined maximum thickness tₘₐₓ.

Returning again to FIG. 9, at block 150, the performance P of the radome 10 is re-assessed with respect to the one or more performance goals 40 using the additional thickness profile TP in the cost function 50, thereby producing an additional thickness profile performance P_{TP} (which may be somewhat different from the initial thickness profile performance P_{TP}).

At block 155, a determination is made as to whether the process flow should be re-directed back to a point immediately before block 140 or should proceed onward to block 170. This determination is made based on whether the current number of iterations n has reached either (i) a predetermined number N or (ii) a quantity Q sufficient to achieve a thickness profile performance P_{TP} that meets or exceeds a target thickness profile performance T_{PTP}. If neither of these two conditions has been met (i.e., “N” for “no”), then the process flow is re-directed along line 160 as shown in FIG. 9 and blocks 140 and 150 are repeated; but if either or both conditions are met (i.e., “Y” for “yes”), then the process flow proceeds onward to block 170.

Finally, at block 170, the best one P_{TP,best} of the thickness profile performances P_{TP} is determined. For example, all of the various thickness profiles TP that have been iterated and assessed may be considered, along with their corresponding thickness profile performances P_{TP}, and the thickness profile TP having the best thickness profile performance P_{TP} (e.g., in terms of performance P, one or more performance goals 40, or the like) may be selected as the best thickness profile TP_{best}. This best thickness profile TP_{best} may be viewed as defining the best candidate (among all the ones iterated and assessed) for producing an optimized design 10ₒₚₜ for the radome 10.

Optionally, the method 100 may further include, at block 180, generating an output file 70 which includes the thickness profile TP that produces the best one P_{TP,best} of the thickness profile performances P_{TP}. For example, the output file 70 may include computer numerically controlled (CNC) instructions 72 configured for use by a CNC machine 74 for producing the radome 10. Relatedly, the method 100 may further include, at block 190, producing the radome 10 by a CNC machine 74 using the output file 70.

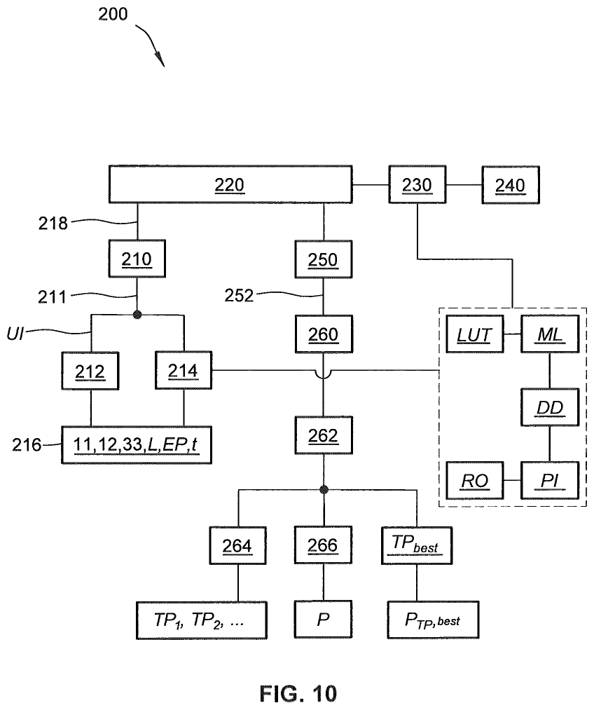

The method 100 may further include, at block 195, outputting a signal 252 configured for enabling a visualization 262 of one or more of: (i) a series or progression 264 of the thickness profiles TP produced as the iterating and re-assessing steps (of blocks 140 and 150, respectively) are repeated for the number of iterations n, which is exemplified in FIG. 10 as a sequence which includes a first thickness profile TP₁, a second thickness profile TP₂, and so forth; (ii) a series or progression 266 of the performance P as the iterating and re-assessing steps 140, 150 are repeated for the number of iterations n; and (iii) the thickness profile TP which produces the best one P_{TP,best} of the thickness profile performances P_{TP}, which is shown in FIG. 10 as TP_{best}. At any given time, the output signal 252 may include information or data relating to the current performance P associated with the thickness profile TP solution under test and/or to the overall best solution up to that point (i.e., TP_{best} and/or P_{TP,best}). And at block 199, the visualization 262 may be displayed on a screen for viewing by a user 212. For example, the visualization 262 may show the series or progression 264 of thickness profiles TP produced as the iterating and re-assessing steps are repeated, either by showing each thickness profile TP one at a time or by showing an accumulated, ongoing sequence of such thickness profiles TP. Additionally or alternatively, the visualization 262 may show the thickness profile TP which produces the best one P_{TP,best} of the thickness profile performances P_{TP}. Optionally, the visualization 262 may also show the thickness profile performance P_{TP} for each thickness profile TP.

FIG. 10 shows a block diagram of a system 200 for determining an optimized design 10ₒₚₜ for a multi-layer radome 10. As shown in the drawing, the system 200 includes an input subsystem 210, a processor 220 and an output subsystem 250.

The input subsystem 210 is configured for receiving one or more inputs 211 from a user 212 (i.e., user inputs UI from a human operator) and/or from another source or device 214 (e.g., a server or database) regarding one or more characteristics or aspects 216 of the radome 10, and for producing an input signal 218 based on the one or more inputs 211. The one or more inputs 211 may include one or more of a geometric shape 11 of the radome 10, a size 12 of the radome 10, a quantity L of the layers 20 in the radome wall 18, the antenna location 33 with respect to the radome 10, one or more of the respective electrical properties EP of one or more of the layers 20, one or more of the respective thicknesses t of one or more of the layers 20 of one or more segments 30, etc. The inputs 211 may also include the respective predetermined minimum and maximum thicknesses tₘᵢₙ, tₘₐₓ for each layer 20 and some or all of the initial values tᵢ for the thicknesses t; these may be obtained from one or more of a look-up table LUT, one or more user inputs UI, and machine learning ML that is based on data DD compiled from previous instances PI of radome optimization RO. The input subsystem 210 may include one or more input devices, such as a keyboard, a mouse, a microphone, a keypad, a trackpad, a stylus, etc.

The processor 220 is operatively connected with the input subsystem 210 and is configured for receiving the input signal 218 from the input subsystem 210. The processor 220 is further configured for: (i) characterizing or parameterizing each of the layers 20 as having a respective set of one or more properties EP and a respective thickness t that varies by segment location 31 along the main axis 13; (ii) providing a respective value tᵢ for the thickness t of each of the layers 20 for each of the segments 30, thereby producing a thickness profile TP; (iii) assessing a performance P of the radome 10 with respect to one or more performance goals 40 using the thickness profile TP in a cost function 50, thereby producing a thickness profile performance P_{TP}; (iv) iterating one or more of the respective thicknesses t at one or more of the segment locations 31 by using an iteration algorithm 60, thereby producing an additional thickness profile TP; (v) re-assessing the performance P of the radome 10 with respect to the one or more performance goals 40 using the additional thickness profile TP in the cost function 50, thereby producing an additional thickness profile performance P_{TP}; (vi) repeating the iterating and re-assessing steps for a number of iterations n; and (vii) determining the thickness profile TP which produces a best one P_{TP,best} of the thickness profile performances P_{TP}, thereby defining the optimized design 10ₒₚₜ for the radome 10.

As shown in FIG. 10, the processor 220 may be operatively connected with or include a memory 230. The memory 230 may be configured to receive, store and/or provide a set of instructions or data 240 for assisting or enabling the processor 220 to perform the steps noted above. For example, the instructions or data 240 may include software code, register addresses and the like for executing one or more of the abovementioned steps, and/or various information or data (such as initial values; for the thicknesses t, various boundary conditions, and the like). As shown in the drawing, one or both of the aforementioned look-up table LUT and machine learning data ML, DD may be part of the processor 220 (e.g., stored in the memory 230), or one or both may be external to the processor 220, with one or both also optionally being accessible to or formed as part of the other source or device 214.

The output subsystem 250 is operatively connected with the processor 220 and is configured for receiving from the processor 220 one or both of (a) the thickness profiles TP produced as the iterating and re-assessing steps are repeated for the number of iterations n, and (b) the thickness profile TP which produces the best one P_{TP,best} of the thickness profile performances P_{TP}. The output subsystem 250 may also be configured for producing an output signal 252 based on one or more of the aforementioned thickness profiles TP. For example, the output subsystem 250 may include an output jack, a wired or wireless broadcast system (e.g., Wi-Fi, Bluetooth, Ethernet, etc.), associated signal conditioning software, and the like.

The system 200 may further include a visualization subsystem 260 configured for receiving the output signal 252 from the output subsystem 250 and for enabling or providing a visualization 262 for the user 212 that is based on the output signal 252. The visualization subsystem 260 may include one or more output devices, such as a screen or monitor for displaying information (including graphic displays) regarding the thickness profiles TP.

As one having skill in the relevant art will appreciate, the method 100 and system 200 of the present disclosure may be presented or arranged in a variety of different configurations and embodiments.

According to one embodiment, a method 100 for determining an optimized design 10ₒₚₜ for a multi-layer radome 10 is provided, wherein the radome 10 has a main axis 13 defining radial and longitudinal directions 14, 17 and a radome wall 18 made of stacked layers 20 and longitudinally contiguous segments 30 with each segment 30 having a respective segment location 31, and with the radome 10 being configured for housing an antenna 32 that is positioned therein at an antenna location 33. The method 100 includes: (i) at block 110, characterizing each of the layers 20 as having a respective set of one or more electrical properties EP and a respective thickness t that varies by segment location 31 along the main axis 13; (ii) at block 120, providing a respective value tᵢ for the thickness t of each of the layers 20 for each of the segments 30, thereby producing a thickness profile TP; (iii) at block 130, assessing a performance P of the radome 10 with respect to one or more performance goals 40 using the thickness profile TP in a cost function 50, thereby producing a thickness profile performance P_{TP}; (iv) at block 140, iterating one or more of the respective thicknesses t at one or more of the segment locations 31 by using an iteration algorithm 60, thereby producing an additional thickness profile TP; (v) at block 150, re-assessing the performance P of the radome 10 with respect to the one or more performance goals 40 using the additional thickness profile TP in the cost function 50, thereby producing an additional thickness profile performance P_{TP}; (vi) at block 160, repeating the iterating and re-assessing steps (of blocks 140 and 150, respectively) for a number of iterations n; and (vii) at block 170, determining the thickness profile TP which produces a best one P_{TP,best} of the thickness profile performances P_{TP}, thereby defining the optimized design 10ₒₚₜ for the radome 10.

The one or more electrical properties EP may include at least one of a dielectric constant DC, a loss tangent LT, a complex permittivity CPT and a complex permeability CPB, and the respective value tᵢ for each thickness t may be identified from one or more of a look-up table LUT, user input UI and machine learning ML based on data D from previous instances PI of radome optimization RO.

In each of the providing and iterating steps (of blocks 120 and 140, respectively), the respective thickness t of each layer 20 for each segment 30 may be selected from between a respective predetermined minimum thickness tₘᵢₙ and a respective predetermined maximum thickness tₘₐₓ.

The performance goals 40 may include one or more of maximizing transmission 42 of radio frequency (RF) energy, minimizing reflection 44 of RF energy, maximizing a bandwidth 46 of RF energy, optimizing a polarization 48 of RF energy, and optimizing a phase insertion 47 of RF energy.

The cost function 50 may be configured to assess an impact Cost, over a range of scan angles R_{scan angles} and over a range of frequencies R_{freqs}, of one or more of: (a) a perpendicular component of reflection Γ_{⊥} of RF energy emitted from the antenna 32 at the antenna location 33 to each of the segment locations 31; (b) a perpendicular component of transmission T_{⊥} of the RF energy; (c) a parallel component of reflection Γ_{∥} of the RF energy; (d) a parallel component of transmission T_{∥} of the RF energy; (e) a polarization 48 of the RF energy; and (f) a phase insertion 47 of the RF energy.

The iteration algorithm 60 may be one or more of a particle swarm optimization algorithm 60_{PSO}, a simulated annealing algorithm 60_{SA}, a greedy local search algorithm 60_{GLS}, a nearest neighbor algorithm 60_{NN}, a branch and bound algorithm 60_{BB}, a gradient descent algorithm 60_{GD}, a genetic algorithm 60_{G}, a stochastic algorithm 60_{S} and a brute force approach 60_{BF}.

The number of iterations n may be at least one of a predetermined number N and a quantity Q sufficient to achieve a thickness profile performance P_{TP} that meets or exceeds a target thickness profile performance T_{PTP}.

The method 100 may further include, at block 180, generating an output file 70 which includes the thickness profile TP that produces the best one P_{TP,best} of the thickness profile performances P_{TP}. For example, the output file 70 may include computer numerically controlled (CNC) instructions 72 configured for use by a CNC machine 74 for producing the radome 10. Relatedly, the method 100 may further include, at block 190, producing the radome 10 by a CNC machine 74 using the output file 70.

The method 100 may further include, at block 195, outputting a signal 252 configured for enabling a visualization 262 of one or more of: (i) a progression 264 of the thickness profiles TP produced as the iterating and re-assessing steps (of blocks 140 and 150, respectively) are repeated for the number of iterations n; (ii) a progression 266 of the performance P as the iterating and re-assessing steps 140, 150 are repeated for the number of iterations n; and (iii) the thickness profile TP which produces the best one P_{TP,best} of the thickness profile performances P_{TP}.

The layers 20 may include alternating layers 21 of one or more skin materials 28 and one or more core materials 29, wherein the one or more skin materials 28 may include at least one of a quartz composite QC, an E-glass EG, a D-glass DG, a polyethylene PE and an aromatic polyamide APA, and wherein the one or more core materials 29 may include at least one of a polyetherimide PEI, a polymethacrylimide PMI, a polyurethane PU, a polycarbonate PC, a polyimide PI, a fluoropolymer FP, a polyaryletherketone PAEK, an acrylonitrile butadiene styrene ABS and a composite material CM.

The radome 10 may be configured as a volume of revolution 11ᵣₑᵥ and the main axis 13 may be an axis of revolution 13ᵣₑᵥ. Additionally or alternatively, the radome 10 may have one of a generally spherical shape 11ₛ, a generally hemispherical shape 11ₕₛ, a generally geodesic shape 11_{g}, a generally elliptical shape 11ₑ and a generally ogive shape 11ₒ.

A multi-layer radome 10 may also be produced by the method 100 of claim 1.

According to another embodiment, a method 100 for determining an optimized design 10ₒₚₜ for a multi-layer radome 10 is provided. In this embodiment, the radome 10 has a main axis 13 defining radial and longitudinal directions 14, 17 and a radome wall 18 made of stacked layers 20 and longitudinally contiguous segments 30 with each segment 30 having a respective segment location 31, with the radome 10 being configured for housing an antenna 32 that is positioned therein at an antenna location 33. The method 100 includes: (i) at block 110, characterizing each of the layers 20 as having a respective set of one or more electrical properties EP and a respective thickness t that varies by segment location 31 along the main axis 13, wherein the one or more electrical properties EP includes at least one of a dielectric constant DC, a loss tangent LT, a complex permittivity CPT and a complex permeability CPB; (ii) at block 120, providing a respective value tᵢ for the thickness t of each of the layers 20 for each of the segments 30, thereby producing a thickness profile TP; (iii) at block 130, assessing a performance P of the radome 10 with respect to one or more performance goals 40 using the thickness profile TP in a cost function 50, thereby producing a thickness profile performance P_{TP}, wherein the performance goals 40 include one or more of maximizing transmission 42 of radio frequency (RF) energy, minimizing reflection 44 of RF energy, maximizing a bandwidth 46 of RF energy, optimizing a polarization 48 of RF energy, and optimizing a phase insertion 47 of RF energy; (iv) at block 140, iterating one or more of the respective thicknesses 1 at one or more of the segment locations 31 by using an iteration algorithm 60, thereby producing an additional thickness profile TP; (v) at block 150, re-assessing the performance P of the radome 10 with respect to the one or more performance goals 40 using the additional thickness profile TP in the cost function 50, thereby producing an additional thickness profile performance P_{TP}; (vi) at block 160, repeating the iterating and re-assessing steps (of blocks 140 and 150, respectively) for a number of iterations n, wherein the number of iterations n is at least one of a predetermined number N and a quantity Q sufficient to achieve a thickness profile performance P_{TP} that meets or exceeds a target thickness profile performance T_{PTP}; and (vii) at block 170, determining the thickness profile TP which produces a best P_{TP,best} one of the thickness profile performances P_{TP}, thereby defining the optimized design 10ₒₚₜ for the radome 10.

According to yet another embodiment, a system 200 for determining an optimized design 10ₒₚₜ for a multi-layer radome 10 is provided, wherein the radome 10 has a main axis 13 defining radial and longitudinal directions 14, 17 and a radome wall 18 made of stacked layers 20 and longitudinally contiguous segments 30 with each segment 30 having a respective segment location 31, with the radome 10 being configured for housing an antenna 32 that is positioned therein at an antenna location 33. The system 200 includes an input subsystem 210, a processor 220 and an output subsystem 250. The input subsystem 210 is configured for receiving one or more inputs 211 from a user 212 or another source or device 214 regarding one or more aspects 216 of the radome 10 and for producing an input signal 218 based on the one or more inputs 211. The processor 220 is configured for receiving the input signal 218 from the input subsystem 210 and for: (i) characterizing each of the layers 20 as having a respective set of one or more electrical properties EP and a respective thickness t that varies by segment location 31 along the main axis 13; (ii) providing a respective value tᵢ for the thickness t of each of the layers 20 for each of the segments 30, thereby producing a thickness profile TP; (iii) assessing a performance P of the radome 10 with respect to one or more performance goals 40 using the thickness profile TP in a cost function 50, thereby producing a thickness profile performance P_{TP}; (iv) iterating one or more of the respective thicknesses t at one or more of the segment locations 31 by using an iteration algorithm 60, thereby producing an additional thickness profile TP; (v) re-assessing the performance P of the radome 10 with respect to the one or more performance goals 40 using the additional thickness profile TP in the cost function 50, thereby producing an additional thickness profile performance P_{TP}; (vi) repeating the iterating and re-assessing steps for a number of iterations n; and (vii) determining the thickness profile TP which produces a best one P_{TP,best} of the thickness profile performances P_{TP}, thereby defining the optimized design 10ₒₚₜ for the radome 10. The output subsystem 250 is configured for receiving from the processor 220, and for producing an output signal 252 based on, one or both of (a) the thickness profiles TP produced as the iterating and re-assessing steps are repeated for the number of iterations n, and (b) the thickness profile TP which produces the best one P_{TP,best} of the thickness profile performances P_{TP}.

The one or more inputs 211 may include one or more of a geometric shape 11 of the radome 10, a size 12 of the radome 10, a quantity L of the layers 20 in the radome wall 18, the antenna location 33 with respect to the radome 10, one or more of the respective electrical properties EP of one or more of the layers 20, and one or more of the respective thicknesses t of one or more of the layers 20.

The system 200 may further include a visualization subsystem 260 configured for receiving the output signal 252 from the output subsystem 250 and for enabling a visualization 262 of one or more of a progression 264 of the thickness profiles TP produced as the iterating and re-assessing steps are repeated for the number of iterations n, a progression 266 of the performance P as the iterating and re-assessing steps 140, 150 are repeated for the number of iterations n, and the thickness profile TP which produces the best one P_{TP,best} of the thickness profile performances P_{TP}.

While various steps of the method 100 have been described as being separate blocks, and various functions of the system 200 have been described as being separate modules or elements, it may be noted that two or more steps may be combined into fewer blocks, and two or more functions may be combined into fewer modules or elements. Similarly, some steps described as a single block may be separated into two or more blocks, and some functions described as a single module or element may be separated into two or more modules or elements. Additionally, the order of the steps or blocks described herein may be rearranged in one or more different orders, and the arrangement of the functions, modules and elements may be rearranged into one or more different arrangements.

(As used herein, a “module” may include hardware and/or software, including executable instructions, for receiving one or more inputs, processing the one or more inputs, and providing one or more corresponding outputs. Also note that at some points throughout the present disclosure, reference may be made to a singular input, output, element, etc., while at other points reference may be made to plural/multiple inputs, outputs, elements, etc. Thus, weight should not be given to whether the input(s), output(s), element(s), etc. are used in the singular or plural form at any particular point in the present disclosure, as the singular and plural uses of such words should be viewed as being interchangeable, unless the specific context dictates otherwise.)

The above description is intended to be illustrative, and not restrictive. While the dimensions and types of materials described herein are intended to be illustrative, they are by no means limiting and are exemplary embodiments. In the following claims, use of the terms “first”, “second”, “top”, “bottom”, etc. are used merely as labels, and are not intended to impose numerical or positional requirements on their objects. As used herein, an element or step recited in the singular and preceded by the word “a” or “an” should be understood as not excluding plural of such elements or steps, unless such exclusion is explicitly stated. Additionally, the phrase “at least one of A and B” and the phrase “A and/or B” should each be understood to mean “only A, only B, or both A and B”. Moreover, unless explicitly stated to the contrary, embodiments “comprising” or “having” an element or a plurality of elements having a particular property may include additional such elements not having that property. And when broadly descriptive adverbs such as “substantially” and “generally” are used herein to modify an adjective, these adverbs mean “mostly”, “mainly”, “for the most part”, “to a significant extent”, “to a large degree” and/or “at least 51 to 99% out of a possible extent of 100%”, and do not necessarily mean “perfectly”, “completely”, “strictly”, “entirely” or “100%”. Additionally, the word “proximate” may be used herein to describe the location of an object or portion thereof with respect to another object or portion thereof, and/or to describe the positional relationship of two objects or their respective portions thereof with respect to each other, and may mean “near”, “adjacent”, “close to”, “close by”, “at” or the like.

This written description uses examples, including the best mode, to enable those skilled in the art to make and use devices, systems and compositions of matter, and to perform methods, according to this disclosure. It is the following claims, including equivalents, which define the scope of the present disclosure.

What is claimed is:

1. A method for determining an optimized design for a multi-layer radome, wherein the radome has a main axis defining radial and longitudinal directions and a radome wall made of stacked layers and longitudinally contiguous segments with each segment having a respective segment location, the radome being configured for housing an antenna that is positioned therein at an antenna location, the method comprising:
characterizing each of the layers as having a respective set of one or more electrical properties and a respective thickness that varies by segment location along the main axis;
providing a respective value for the thickness of each of the layers for each of the segments, thereby producing a thickness profile;
assessing a performance of the radome with respect to one or more performance goals using the thickness profile in a cost function, thereby producing a thickness profile performance;
iterating one or more of the respective thicknesses at one or more of the segment locations by using an iteration algorithm, thereby producing an additional thickness profile;
re-assessing the performance of the radome with respect to the one or more performance goals using the additional thickness profile in the cost function, thereby producing an additional thickness profile performance;
repeating the iterating and re-assessing steps for a number of iterations; and
determining the thickness profile which produces a best one of the thickness profile performances, thereby defining the optimized design for the radome.

2. The method of claim 1, wherein the one or more electrical properties includes at least one of a dielectric constant, a loss tangent, a complex permittivity and a complex permeability.

3. The method of claim 1, wherein the respective value for each thickness is identified from one or more of a look-up table, user input and machine learning based on data from previous instances of radome optimization.

4. The method of claim 1, wherein in each of the providing and iterating steps, the respective thickness of each layer for each segment is selected from between a respective predetermined minimum thickness and a respective predetermined maximum thickness.

5. The method of claim 1, wherein the performance goals include one or more of maximizing transmission of radio frequency (RF) energy, minimizing reflection of RF energy, maximizing a bandwidth of RF energy, optimizing a polarization of RF energy and optimizing a phase insertion of RF energy.

6. The method of claim 1, wherein the cost function is configured to assess an impact, over a range of scan angles and over a range of frequencies, of one or more of:
a perpendicular component of reflection of radio frequency (RF) energy emitted from the antenna at the antenna location to each of the segment locations;
a perpendicular component of transmission of the RF energy;
a parallel component of reflection of the RF energy;
a parallel component of transmission of the RF energy;
a polarization of the RF energy; and
a phase insertion of the RF energy.

7. The method of claim 1, wherein the iteration algorithm is one or more of a particle swarm optimization algorithm, a simulated annealing algorithm, a greedy local search algorithm, a nearest neighbor algorithm, a branch and bound algorithm, a gradient descent algorithm, a genetic algorithm, a stochastic algorithm and a brute force approach.

8. The method of claim 1, wherein the number of iterations is at least one of a predetermined number and a quantity sufficient to achieve a thickness profile performance that meets or exceeds a target thickness profile performance.

9. The method of claim 1, further comprising:
generating an output file which includes the thickness profile that produces the best one of the thickness profile performances.

10. The method of claim 9, wherein the output file includes computer numerically controlled (CNC) instructions configured for use by a CNC machine for producing the radome.

11. The method of claim 10, further comprising:
producing the radome by a CNC machine using the output file.

12. The method of claim 1, further comprising:
outputting a signal configured for enabling a visualization of one or more of:
a progression of the thickness profiles produced as the iterating and re-assessing steps are repeated for the number of iterations;
a progression of the performance as the iterating and re-assessing steps are repeated for the number of iterations; and
the thickness profile which produces the best one of the thickness profile performances.

13. The method of claim 1, wherein the layers include alternating layers of one or more skin materials and one or more core materials, wherein the one or more skin materials includes at least one of a quartz composite, an E-glass, a D-glass, a polyethylene and an aromatic polyamide, and wherein the one or more core materials includes at least one of a polyetherimide, a polymethacrylimide, a polyurethane, a polycarbonate, a polyimide, a fluoropolymer, a polyaryletherketone, an acrylonitrile butadiene styrene and a composite material.

14. The method of claim 1, wherein the radome is configured as a volume of revolution and the main axis is an axis of revolution.

15. The method of claim 1, wherein the radome has one of a generally spherical shape, a generally hemispherical shape, a generally geodesic shape, a generally elliptical shape and a generally ogive shape.

16. A multi-layer radome produced by the method of claim 1.

17. A method for determining an optimized design for a multi-layer radome, wherein the radome has a main axis defining radial and longitudinal directions and a radome wall made of stacked layers and longitudinally contiguous segments with each segment having a respective segment location, the radome being configured for housing an antenna that is positioned therein at an antenna location, the method comprising:
characterizing each of the layers as having a respective set of one or more electrical properties and a respective thickness that varies by segment location along the main axis, wherein the one or more electrical properties includes at least one of a dielectric constant, a loss tangent, a complex permittivity and a complex permeability;
providing a respective value for the thickness of each of the layers for each of the segments, thereby producing a thickness profile;
assessing a performance of the radome with respect to one or more performance goals using the thickness profile in a cost function, thereby producing a thickness profile performance, wherein the performance goals include one or more of maximizing transmission of radio frequency (RF) energy, minimizing reflection of RF energy, maximizing a bandwidth of RF energy, optimizing a polarization of RF energy and optimizing a phase insertion of RF energy;
iterating one or more of the respective thicknesses at one or more of the segment locations by using an iteration algorithm, thereby producing an additional thickness profile;
re-assessing the performance of the radome with respect to the one or more performance goals using the additional thickness profile in the cost function, thereby producing an additional thickness profile performance;
repeating the iterating and re-assessing steps for a number of iterations, wherein the number of iterations is at least one of a predetermined number and a quantity sufficient to achieve a thickness profile performance that meets or exceeds a target thickness profile performance; and
determining the thickness profile which produces a best one of the thickness profile performances, thereby defining the optimized design for the radome.

18. A system for determining an optimized design for a multi-layer radome, wherein the radome has a main axis defining radial and longitudinal directions and a radome wall made of stacked layers and longitudinally contiguous segments with each segment having a respective segment location, the radome being configured for housing an antenna that is positioned therein at an antenna location, comprising:
an input subsystem configured for receiving one or more inputs from a user or another source or device regarding one or more aspects of the radome and for producing an input signal based on the one or more inputs;
a processor configured for receiving the input signal from the input subsystem and for:
characterizing each of the layers as having a respective set of one or more electrical properties and a respective thickness that varies by segment location along the main axis;
providing a respective value for the thickness of each of the layers for each of the segments, thereby producing a thickness profile;
assessing a performance of the radome with respect to one or more performance goals using the thickness profile in a cost function, thereby producing a thickness profile performance;
iterating one or more of the respective thicknesses at one or more of the segment locations by using an iteration algorithm, thereby producing an additional thickness profile;
re-assessing the performance of the radome with respect to the one or more performance goals using the additional thickness profile in the cost function, thereby producing an additional thickness profile performance;
repeating the iterating and re-assessing steps for a number of iterations; and
determining the thickness profile which produces a best one of the thickness profile performances, thereby defining the optimized design for the radome; and
an output subsystem configured for receiving from the processor, and for producing an output signal based on, one or both of (i) the thickness profiles produced as the iterating and re-assessing steps are repeated for the number of iterations, and (ii) the thickness profile which produces the best one of the thickness profile performances.

19. The system of claim 18, wherein the one or more inputs include one or more of a geometric shape of the radome, a size of the radome, a quantity of the layers in the radome wall, the antenna location with respect to the radome, one or more of the respective electrical properties of one or more of the layers, and one or more of the respective thicknesses of one or more of the layers.

20. The system of claim 18, further comprising:
a visualization subsystem configured for receiving the output signal from the output subsystem and for enabling a visualization of one or both of:
a progression of the thickness profiles produced as the iterating and re-assessing steps are repeated for the number of iterations;
a progression of the performance as the iterating and re-assessing steps are repeated for the number of iterations; and
the thickness profile which produces the best one of the thickness profile performances.
